(19) United States
(12) Patent Application Publication
(10) Pub. No.: US 2012/0214312 A1
(43) Pub. Date: Aug. 23, 2012

(54) Method of plasma etching and plasma chamber cleaning using F2 and COF2

(75) Inventor: Marcello Riva, Hannover (DE)

(73) Assignee: SOLVAY SA, Brussels (BE)

(21) Appl. No.: 13/504,099

(22) PCT Filed: Oct. 28, 2010
(86) PCT No.: PCT/EP2010/066407

§ 371 Date: Apr. 25, 2012

(30) Foreign Application Priority Data
Oct. 30, 2009 (EP) 09174705.5

(51) Int. Cl. H01L 21/3065; C01B 7/20; C01B 31/00; B08B 9/08

(52) U.S. Cl. 438/710; 134/1.1; 423/500; 423/415.1; 257/E21.218

(57) ABSTRACT

For the plasma assisted manufacture of semiconductors, photovoltaic cells, thin film transistor liquid crystal displays and micro-electromechanical systems, and for chamber cleaning, F₂ or COF₂ is applied as etchant. It was found that a plasma emitter providing microwaves with a frequency of equal to or greater than 15 MHz provides plasma very effectively.

### CROSS-REFERENCE TO RELATED APPLICATIONS

The present application is a U.S. national stage entry under 35 U.S.C. §371 of International Application No. PCT/EP2010/066407 filed Oct. 28, 2010, which claims priority to European Patent Application No. 09174705.5 filed Oct. 30, 2009, the whole content of this application being herein incorporated by reference for all purposes.

### TECHNICAL FIELD OF THE INVENTION

The invention concerns a method for plasma etching and removing deposits, especially in a chamber cleaning process using F₂ or carbonyl fluoride, as an etching gas; and to a plasma.

### BACKGROUND OF THE INVENTION

During the manufacture of semiconductors, photovoltaic cells, thin film transistor (TFT) liquid crystal displays, and micro-electromechanical systems (MEMS), often consecutive steps of deposition of material, e.g., by chemical vapor deposition (CVD), on a substrate in a treatment chamber are performed. The substrate, during the treatment, is typically located on a support provided inside the treatment chamber; the treatment processes are often plasma-assisted. During the deposition step, especially in CVD steps, deposits are often not only formed on the substrate, but also on the walls and other interior parts of the chamber. In order to prevent contamination problems during subsequent manufacturing runs, such materials are suitably removed.

It was observed that elemental fluorine is a very effective agent both for etching and for cleaning the chambers to remove undesired deposits. Processes of this kind are for example described in WO 2007/116033 (which describes the use of fluorine and certain mixtures as etchant and chamber cleaning agent), WO 2009/080615 (which describes the manufacture of MEMS), 2009/092453 (which describes the manufacture of solar cells), and in unpublished PCT application N° PCT/EP 2010/066109 (corresponding to EP patent application 09174034.0) which concerns the manufacture of TFTs. EP-A-1138802 discloses that amorphous silicon, also denoted as a-silicon or α-silicon, can be cleaned thermally with fluorine gas, but that silicon oxide or silicon nitride cannot be removed by this method. Carbonyl fluoride (COF₂) can also be applied as etchant and chamber cleaning agent.

Often, the steps of etching or chamber cleaning are assisted by plasma. Plasma can be generated by applying a high frequency voltage between opposed electrodes or in a magnetron which provides microwaves the frequency of which is to the upper range of radio frequencies. The electromagnetic waves heat up the gas phase inside the plasma reactor. Atoms with high reactivity are formed, e.g., F atoms which then etch matter away, forming volatile reaction products. Amorphous, crystalline or microcrystalline silicon, for example, forms volatile SiF₄ which can be removed from the plasma reactor. Undesired deposits on the inner walls of the reactor, e.g., deposits of silicon, silicon nitride can likewise be transformed into volatile reaction products.

Apparatuses applying radio frequency and microwave frequency to provide plasma useful for dry etching are known. U.S. Pat. No. 4,401,054, for example, provides microwaves with a wavelength of 2.45 GHz and radio frequency of 13.56 MHz.

Problem of the present invention is to provide an efficient process for etching and chamber cleaning using F₂ or COF₂ assisted by a radio frequency plasma.

### SUMMARY OF THE INVENTION

The process of the present invention relates to the etching of substrates in a plasma chamber, or to the removing of deposits from a solid body comprising a step of providing an etching gas comprising or consisting of F₂ or COF₂ as etchant, wherein the etching or chamber cleaning is assisted by providing radio frequency to generate plasma wherein the radio frequency is equal to or greater than 15 MHz, preferably equal to or greater than 30 MHz, very preferably, equal to or greater than 40 MHz.

Reactive species, especially fluorine radicals, are generated from molecular fluorine or COF₂.

Fluorine is preferably applied as etching gas or chamber cleaning gas.

The term “generated from molecular fluorine” is understood to denote in particular that molecular fluorine (F₂) is initially present in the gas used to generate the reactive species by means of high frequency plasma.

Basically, the range of “radio frequency” is commonly considered to extend from 30 kHz to 300 GHz. Within these boundaries, the range of microwaves includes waves having a frequency from 300 MHz to 300 GHz. To distinguish the range of microwave frequency from the range of radio frequencies with a lower frequency, often electromagnetic waves having a frequency of 30 kHz to 300 MHz are denoted as “radio frequency waves”, or in short, “radio frequency”, and electromagnetic waves having a frequency of 300 MHz to 300 GHz are denoted as “microwaves”. In the context of the present invention, these definitions are applied, and the term “radio frequency” generally denotes that the frequency of the generated field is in the range of 30 kHz to 300 MHz not including the “microwave” with frequencies in a range of more than 300 MHz to 300 GHz.

The plasma gas comprises reactive species generated from F₂ or COF₂. The term “reactive species” is understood to denote in particular an atomic fluorine containing plasma. Preferably, the atomic fluorine containing plasma is generated from molecular F₂ which is initially present in the gas which is converted into plasma.

Preferably, the radio frequency, or in other words, the frequency of the generated field, is equal to or lower than 100 MHz. More preferably, the radio frequency is from 40 to 100 MHz, especially from 40 to 80 MHz. A typical frequency is 40 MHz and 60 MHz. A useful frequency is, for example, centered at about 40.68 MHz.

### DETAILED DESCRIPTION

In the first particular embodiment of the method according to the invention, the gas pressure is generally from 0.5 to 50 Ton, often from 1 to 10 Ton and preferably equal to or less than 5 Ton.

In the first particular embodiment of the method according to the invention, the residence time of the gas is generally from 1 to 180 s, often from 30 to 70 s and preferably from 40 to 60 s.

In the first particular embodiment of the method according to the invention, the power applied to generate the plasma is generally from 1 to 100000 W, often from 5000 to 60000 W and preferably from 10000 to 40000 W.

In the second particular embodiment of the method according to the invention, the gas pressure is generally from 50 to 500 Ton, often from 75 to 300 Ton and preferably from 100 to 200 Ton.

In the second particular embodiment of the method according to the invention, the residence time of the gas is generally from 50 to 500 s, often from 100 to 300 s and preferably from 150 to 250 s.

Surprisingly, the efficiency of the plasma process improves compared to radio frequency plasma provided by radio frequencies in a lower frequency range even at a comparable power level or the emitter.

The process of the invention, according to one embodiment of the invention, is especially suitable to etch substrates in the manufacture of semiconductors, photovoltaic cells, thin film transistor liquid crystal displays and micro-electromechanical systems. The term “substrate” denotes, for example, solar cells, usually manufactured from monocrystalline blocks of boron-doped silicon (P-type doping) or from cast silicon ingots (polycrystalline silicon, P-type doped with boron) by sawing wafers in desired size out of the bulk material wherein optionally silicon doped with phosphorous is formed to provide an N-type doped coating; semiconductors. The term “substrate” further denotes TFTs; micro-electromechanical devices or machines, generally ranging in the size from a micrometer to a millimeter, for example, inkjet printers operating with piezoelectrics or thermal bubble ejection, accelerometers for cars, e.g., for airbag deployment in collisions, gyroscopes, silicon pressure sensors e.g., for monitoring car tires or blood pressure, optical switching technology or bio-MEMS applications in medical and health-related technologies.

In the other embodiment according to the invention concerning the removal of deposits, the deposits may comprise any element or any compound which forms volatile reaction products with atomic fluorine. The deposits may comprise especially amorphous silicon, microcrystalline silicon, or crystalline silicon, poly silicon, silicon nitride, phosphorous, silicon hydrides silicon oxynitrides, fluorine doped or carbon doped silica glass and other low-k dielectrics base on SiO₂, or metals, e.g., tungsten, from a solid body, wherein the solid body generally comprises or consists of an electrically conductive material such as for example aluminum, or aluminum alloys in particularly aluminum/magnesium alloys, stainless steel and silicon carbide. Aluminum and aluminum alloys are preferred. In a preferred embodiment, the solid body is an interior part of a treatment chamber for manufacture of semiconductors, flat panel displays, MEMS or photovoltaic elements. In a particular aspect, the solid body is an electrode suitable to create an electrical field in a CVD process, which is preferably made of electrically conductive material in particular such as described above.

The method according to the invention is particularly suitable for cleaning deposits in process chambers used for the manufacture of photovoltaic elements. The deposits may comprise any element or any compound which forms volatile reaction products with atomic fluorine, e.g., deposits comprising metals, e.g., W, amorphous silicon, microcrystalline silicon, or crystalline silicon, silicon nitride or silicon hydrides silicon oxynitrides, fluorine doped or carbon doped silica glass and other low-k dielectrics base on SiO₂, or metals, e.g., tungsten. This method can also be denoted as “chamber cleaning process”.

In one preferred aspect, the gas consists or consists essentially of molecular fluorine. In another aspect, a mixture comprising molecular fluorine and e.g., an inert gas, such as nitrogen, argon, xenon or mixtures thereof, is used. Preferably the etching gas is selected from etching gases consisting of F₂ and mixtures comprising or consisting of F₂ and N₂ and/or argon. In particular, mixtures of nitrogen, argon and molecular fluorine are used. In this case, the content of molecular fluorine in the mixture is typically equal to or less than 50% molar. Preferably, this content is equal to or less than 20% molar. Suitable mixtures are disclosed for example in WO 2007/116033 in the name of the applicant, the entire content of which is incorporated by reference into the present patent application. A particular mixture consists essentially of about 10% molar argon, 70% molar nitrogen, and 20% molar F₂.

In a particular embodiment of this aspect, the content of molecular fluorine in the mixture with an inert gas as described above is more than 50% molar. Preferably, this content is equal to or more than 80% molar, for example about 90% molar. In this particular embodiment, argon is a preferred inert gas. A mixture consisting of about 90 molar % of molecular fluorine and about 10 molar % of argon is more particularly preferred. In this particular embodiment of this aspect, the content of molecular fluorine in the mixture with an inert gas as described above is equal to or lower than 95% molar. Preferably, the molecular fluorine content of the gas is from more than 50% molar to 95% molar, preferably from 80 to 90% molar and the inert gas content is from 5% molar to 50% molar, preferably from 10% molar to 20% molar

Molecular fluorine for use in the present invention can be produced for example by heating suitable fluorometallates such as fluoronickelate or manganese tetrafluoride. Preferably, the molecular fluorine is produced by electrolysis of a molten salt electrolyte, in particular a potassium fluoride/hydrogen fluoride electrolyte, most preferably KF.2HF.

Preferably, purified molecular fluorine is used in the present invention. Purification operations which are suitable to obtain purified molecular fluorine for use in the invention include removal of particles, for example by filtering or absorption and removal of starting materials, in particular HF, for example by absorption, and impurities such as in particular CF₄ and O₂. Typically, the HF content in molecular fluorine used in the present invention is less than 10 ppm molar. Typically, the fluorine used in the present invention contains at least 0.1 molar ppm HF.

In a preferred embodiment, purified molecular fluorine for use in the present invention is obtained by a process comprising
(a) electrolysis of a molten salt, in particular as described above, to provide crude molecular fluorine containing HF, particles and optional impurities;
(b) an operation to reduce the HF content relative to the HF content of crude molecular fluorine, comprising for example an adsorption on sodium fluoride and preferably reducing the HF content in the molecular fluorine to the values mentioned here before;
(c) an operation to reduce the particle content relative to the particle content of crude molecular fluorine, comprising for example passing a fluorine stream containing particles through a solid absorbent such as for example sodium fluoride.

The molecular fluorine, in particular produced and purified as described here before, can be supplied to the method according to the invention, for example, in a transportable container. This method of supply is preferred when mixtures of fluorine gas with an inert gas in particular as described above are used in the method according to the invention.

Alternatively, the molecular fluorine can be supplied directly from its manufacture and optional purification to the method according to the invention, for example through a gas delivery system connected both to the silicon hydride removal step and to the fluorine manufacture and/or purification. This embodiment is particularly advantageous, if the gas used in the method according to the invention consists or consists essentially of molecular fluorine.

In these mixtures, the content of F₂ can vary broadly, from e.g., 1% by volume to 99% by volume. Often, the content of F₂ is equal to or greater than 10% by volume. Often, it is equal to or lower than 80% by volume. The higher the concentration of F₂, the higher is the speed of etching or the speed of the chamber cleaning, but possibly the lower the selectivity.

It is understood that these particular conditions also apply to the plasma according to the invention and the use according to the invention as described below.

In one aspect of the first particular embodiment, the treatment is carried out by the remote plasma technology which may be performed in an inductively coupled plasma for COF₂. In another aspect of this embodiment, in-situ plasma is generated. For example, such in-situ plasma is generated inside a treatment chamber comprising a device suitable for generating plasma from the gases described above, in particular from purified molecular fluorine especially capacitatively coupled. Suitable devices include, for example, a pair of electrodes capable of generating a high frequency electrical field.

If desired, the radio frequency, preferably having a frequency in the range of 40 MHz to 100 MHz, more preferably, in the range of 40 MHz to 80 MHz, can be combined with a microwave emitter, e.g., a magnetron, especially for etching.

In principle, a magnetron emitting microwaves with any wavelength of 300 MHz to 300 GHz may be applicable in this embodiment. Magnetrons emitting waves with a frequency of 2.45 GHz are preferred because they are commonly used. Other microwave frequencies often used are centered on 915 MHz, 5.8 GHz and 24.125 GHz.

Apparatuses which can be applied for the process of the present invention are commercially available.

In a preferred embodiment, the invention concerns a method for removing amorphous silicon or silicon hydride, and especially for removing α-silicon, microcrystalline silicon and crystalline silicon from the surface of a solid body which comprises treating the silicon hydride with reactive species generated from molecular fluorine assisted by high frequency plasma wherein the frequency of the generated field is preferably in the range of 40 to 80 MHz.

Surprisingly, molecular fluorine is particularly efficient for removal of amorphous silicon and silicon hydrides thus allowing for good cleaning efficiency and reduced cleaning time. Fluorine gas has no global warming potential and may be used with relatively low energy consumption compared for example to conventionally used NF₃ cleaning gas, while efficiently removing the silicon hydride deposits and the deposits of amorphous silicon.

“Silicon hydride” is understood to denote in particular a solid containing silicon and hydrogen. The hydrogen atom content in the solid phase is generally less than 1 mole per mole of silicon. This content is generally equal to or higher than 0.01 mole/mole silicon. Often this content is equal to or higher than 0.1 mole/mole silicon.

Often, the concentration of H in the silicon hydride is between 0.1 and 0.35 mole/mole silicon in an amorphous phase. It is between 0.03 and 0.1 mole/mole silicon in a microcrystalline phase.

The term “reactive species” is understood to denote in particular a fluorine containing plasma or atomic fluorine.

The term “generated from molecular fluorine” is understood to denote in particular that molecular fluorine (F₂) is initially present in the gas used to generate the reactive species by means of a high frequency plasma.

Typically, amorphous silicon or silicon hydride have been deposited on the surface of the solid body by chemical vapor deposition using a silane containing deposition gas. Typically the deposition gas comprises a silane and hydrogen. Examples of suitable silanes include SiH₄ and Si₂H₆. When a deposition gas comprising a silane and hydrogen is used, the silane content in the deposition gas is generally at least 50%, often at least 60%. When a deposition gas comprising silane and hydrogen is used, the silane content in the deposition gas is generally at most 90%, often equal to or less than 80%.

EP-A-1138802 teaches that it carries out a plasma CVD process with silane and hydrogen to form an amorphous silicon layer. The materials which are removed in the present invention are amorphous silicon and silicon hydrides, in particular as defined above. The deposition process can be carried out so as to control the hydrogen content of the silicon hydride and the crystallinity thereof.

The silicon hydrides which can be removed by the method of the invention are generally selected from amorphous and microcrystalline silicon hydrides. In one aspect the silicon hydrides consist essentially of amorphous silicon hydride. In another aspect the silicon hydrides consist essentially of microcrystalline silicon hydride. In yet another aspect, the silicon hydrides comprise amorphous and microcrystalline silicon hydride.

In the present invention, molecular fluorine (F₂) is used as an essential component of the gas.

The frequency of the generated field is preferably from 40 to 80 MHz. A typical frequency is preferably from 40 MHz and 60 MHz.

The invention concerns also a plasma which has been obtained by exposing a molecular fluorine or COF₂ containing gas as described above, in particular a gas consisting or consisting essentially of molecular fluorine to a high-frequency electrical field having a frequency of from 40 to 80 MHz. The invention concerns also the use of such plasma to the etching of substrates in the frame of a in a semiconductor, a flat panel display or a photovoltaic element manufacturing process or to clean a treatment chamber used in a semiconductor, a flat panel display or a photovoltaic element manufacturing process.

The preferred embodiments of this plasma, especially relating to the preferred pressure, power, specific gas or gas mixture are those preferred embodiments mentioned above.

Preferably, the molecular fluorine containing gas has been exposed to the high-frequency electrical field at a gas pressure from 0.5 to 50 Ton.

Preferably, the power which has been applied to generate the plasma is from 5000 to 60000 W, preferably from 10000 to 40000 W.

Still another aspect of the present invention concerns the use of the plasma as described above to clean a treatment chamber used in a semiconductor, a MEMS, a flat panel display or a photovoltaic element manufacturing process.

In the method according to the invention and the particular embodiments thereof, the treatment is generally carried out for a time sufficient to reduce the quantity of the deposit, e.g., amorphous silicon, α-silicon, microcrystalline silicon, poly silicon and silicon hydride on the surface to less than 1% preferably less than 0.1% relative to its initial content.

The invention concerns also a process for the manufacture of a product wherein at least one treatment step for the manufacture of the product is carried out in a treatment chamber and silicon hydride is deposited on interior parts of the treatment chamber, for example on an electrode, which process comprises cleaning said interior part by the method according to the invention. Typically, the manufacture of the product comprises at least one chemical vapor deposition step of amorphous, polycrystalline and/or microcrystalline silicon or silicon hydride, as described above, onto a substrate. Typical products are selected from a semiconductor, a MEMS, a flat panel display and a photovoltaic element such as a solar panel.

### EXAMPLES

The examples here after are intended to illustrate the invention without however limiting it.
General: The H content in the examples is indicated as molar percentage. The percentages of F₂, Ar and N₂ are given in molar percentage, too.

### Example 1

### Remote Plasma Cleaning with Molecular Fluorine

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending on the plasma conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. After removing the panel substrate from the chamber, a gas consisting essentially of molecular fluorine is introduced at 35 slm into the chamber through a remote plasma (RPS) system (10 kW) at a pressure of 100 mb. After 3 min treatment, the microcrystalline and amorphous Si:H layer is substantially removed from the chamber walls and from the counter electrode.

### Example 2

### Remote Plasma Cleaning with Molecular Fluorine Mixture with Inert Gas

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. After removing the panel substrate from the chamber, a gas mixture consisting of molecular fluorine (20%) and nitrogen (70%) and Ar (10%) is introduced into the chamber at 35 slm through an RPS system (40 kW) at a pressure of 200 mbar After 10 min treatment, the microcrystalline and amorphous Si:H layer is substantially removed from the chamber walls and from the counter electrode.

### Example 3

### Thermal Cleaning with Molecular Fluorine Comparison Example

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. After removing the panel substrate from the chamber, a gas consisting essentially of molecular fluorine, previously heated to 200° C., is introduced into the chamber at 35 slm at a pressure of 220 mbar. After 2 min treatment, the microcrystalline and amorphous Si:H layer is substantially removed from the chamber walls and from the counter electrode.

### Example 4

### In situ Plasma Cleaning with Molecular Fluorine Comparison Example

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. After removing the panel substrate from the chamber, a gas consisting essentially of molecular fluorine is introduced at 10 slm into the chamber at a pressure of 5 mb. The in situ plasma operating at 13.56 MHz source is activated and stable plasma is reached. After 5 min treatment, the microcrystalline and amorphous Si:H layer is substantially removed from the chamber walls and from the counter electrode.

### Example 5

### In situ Plasma Cleaning with Molecular Fluorine Mixture with Inert Gas

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. After removing the panel substrate from the chamber, a gas mixture consisting of molecular fluorine (20%) and nitrogen (70%) and Ar (10%) is introduced at 10 slm into the chamber at a pressure of 5 mb. The in situ plasma source is activated and a stable plasma is reached. After 20 min treatment, the microcrystalline and amorphous Si:H layer is substantially removed from the chamber walls and from the counter electrode

### Example 6

### In situ Plasma Cleaning with Molecular Fluorine

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. The plasma source at high frequency (40 MHz) allow depositing the active aSi:H and μmSi:H at an improved rate and with good uniformity. After removing the panel substrate from the chamber, a gas consisting essentially of molecular fluorine is introduced at 10 slm into the chamber at a pressure of 5 mb. The in situ plasma source is activated and a stable plasma is reached. After 3 min treatment, the microcrystalline and amorphous Si:H layer is substantially removed from the chamber walls and from the counter electrode.

### Example 7

### In situ Plasma Cleaning with Molecular Fluorine Mixture with Inert Gas

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. The plasma source at high frequency (40 MHz) allow depositing the active aSi:H and μmSi:H at an improved rate and with good uniformity. After removing the panel substrate from the chamber, a gas mixture consisting of molecular fluorine (20%) and nitrogen (70%) and Ar (10%) is introduced at 10 slm into the chamber at a pressure of 5 mb. The in situ plasma source is activated and a stable plasma is reached. After 15 min treatment, the microcrystalline and amorphous Si:H layer is substantially removed from the chamber walls and from the counter electrode

### Example 8

### In situ Plasma Cleaning with Molecular Fluorine Mixture with Inert Gas

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. The plasma source at high frequency (60 MHz) allow depositing the active aSi:H and μmSi:H at an improved rate and with good uniformity. After removing the panel substrate from the chamber, a gas consisting essentially of molecular fluorine is introduced at 10 slm into the chamber at a pressure of 5 mb. The in situ plasma source is activated and stable plasma is reached. After 2.5 min treatment, the microcrystalline and amorphous Si:H layer is substantially removed from the chamber walls and from the counter electrode.

### Example 9

### In situ Plasma Cleaning with Molecular Fluorine Mixture with Inert Gas

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. The plasma source at high frequency (60 MHz) allow depositing the active aSi:H and μm Si:H at an improved rate and with good uniformity. After removing the panel substrate from the chamber, a gas mixture consisting of molecular fluorine (20%) and nitrogen (70%) and Ar (10%) is introduced at 10 slm into the chamber at a pressure of 5 mb. The in situ plasma source is activated and a stable plasma is reached. After 13 min treatment, the microcrystalline and amorphous Si:H layer is substantially removed from the chamber walls and from the counter electrode.

### Example 10

### In situ Plasma Cleaning with Molecular Fluorine Mixture with Inert Gas for Silicon Nitride Removal

### Example 10

### In situ Plasma Cleaning with Molecular Fluorine Mixture with Low Inert Gas Content (10% Ar)

Fluorine mixtures with low concentration of inert gas are of interest because they can be transported in bulk (tube trailers) almost preserving the high reactivity of pure fluorine.

In the manufacture of a solar panel a chemical vapor deposition step using silane gas and H₂ and doping gases containing PH₃ is carried out to deposit a silicon containing layer on a panel substrate mounted on a support within a treatment chamber having inside walls made of aluminum alloy. Depending upon deposition conditions and concentration of reagents, it is observed that after the PECVD step, microcrystalline and/or amorphous Si:H deposits are present on the inside walls and on the counter electrode of the chamber. The concentration of H in the Silicon Hydride is between 10% and 25% in the amorphous phase, whilst it is between 3% and 10% in the microcrystalline phase. The plasma source at high frequency (60 MHz) allow depositing the active a-Si:H and μc-Si:H at an improved rate and with good uniformity. After removing the panel substrate from the chamber, a gas mixture consisting of molecular fluorine (90%) and Ar (10%) is introduced at 10 slm into the chamber at a pressure of 5 mb. The in situ plasma source is activated and a stable plasma is reached. After 2.5 min treatment, the microcrystalline and amorphous Si:H layer is substantially removed from the chamber walls and from the counter electrode. It has not been possible to measure any deviation in etching rate between pure fluorine and the above mentioned mixture.

Should the disclosure of any patents, patent applications, and publications which are incorporated herein by reference conflict with the description of the present application to the extent that it may render a term unclear, the present description shall take precedence.

1. A process for the etching of substrates in a plasma chamber, or for to the removing of deposits from a solid body comprising a step of providing an etching gas comprising F₂ or COF₂ as etchant, wherein the etching or chamber cleaning is assisted by providing radio frequency to generate plasma wherein the radio frequency is centered between about 40 MHz and 80 MHz.

2. The process of claim 1 wherein the plasma is direct plasma.

3. The process of claim 1 wherein the plasma is remote plasma.

4. The process of claim 1, wherein the etching gas is selected from the group consisting of F₂ and mixtures comprising or consisting of F₂ and N₂ and/or argon.

5. The process of claim 1, wherein the pressure of the etching gas is equal to or greater than 0.01 Bar (abs.).

6. The process of claim 1, wherein the pressure of the etching gas is equal to or lower than ambient pressure.

7. The process of claim 1, wherein the content of F₂ in the etching gas is equal to or greater than 10% by volume.

8. The process of claim 1, wherein substrates are etched in the manufacture of semiconductors, photovoltaic cells, thin film transistor liquid crystal displays, and micro-electromechanical systems.

9. The process of claim 1, being a chamber cleaning process.

10. (canceled)

11. The process according to claim 1, wherein power applied to generate the plasma is from 5000 to 60000 W.

12. A plasma obtained by exposing a gas containing molecular fluorine or COF₂ in accordance with the process of claim 11 to a high-frequency electrical field having a frequency of from 40 to 80 MHz.

13. The plasma according to claim 12, wherein the gas comprising molecular fluorine exposed to the high-frequency electrical field is at a gas pressure from 0.5 to 50 Torr.

14. The plasma according to claim 12, wherein power applied to generate the plasma is from 5000 to 60000 W.

15. A method for cleaning a treatment chamber used in a semiconductor, MEMS, a flat panel display or a photovoltaic element manufacturing process, comprising a step of providing a plasma by exposing a gas containing molecular fluorine or COF₂ to a high-frequency electrical field having a frequency of from 40 to 80 MHz wherein power applied to generate the plasma is from 5000 to 60000 W.

16. The method of claim 15 wherein the gas consists essentially of fluorine.

17. The method of claim 15 wherein the gas containing molecular fluorine exposed to the high frequency field is at a pressure from 0.5 to 50 Torr.

18. The method of claim 15 wherein the power applied to generate the plasma is from 10000 to 40000 W.
